(19) United States
(12) Patent Application Publication
(10) Pub. No.: US 2026/0173787 A1
(43) Pub. Date: Jun. 18, 2026

(54) MANUFACTURING METHOD FOR SEMICONDUCTOR DEVICE

(71) Applicant: CANON KABUSHIKI KAISHA, Tokyo (JP)

(72) Inventors: TETSUYA KIMURA, Tokyo (JP); KOSUKE ASANO, Kanagawa (JP)

(21) Appl. No.: 19/411,972

(22) Filed: Dec. 8, 2025

(30) Foreign Application Priority Data
Dec. 13, 2024 (JP) 2024-219008

(51) Int. Cl. H10P 52/40; H10P 76/20; H10W 20/00; H10W 20/41

(52) U.S. Cl. CPC H10P 52/403; H10P 76/2041; H10W 20/062; H10W 20/089; H10W 20/435

(57) ABSTRACT

A manufacturing method for a semiconductor device includes forming a depression in an interlayer dielectric film placed on a semiconductor substrate, forming a planarized film made of a first cured product of a first curable composition on the interlayer dielectric film so as to cover the depression, forming, on the planarized film, a pattern made of a second cured product of a second curable composition and having an opening on the depression, etching the planarized film by using the pattern so as to form a trench in the first cured product in the depression, forming a metal film on the interlayer dielectric film so as to fill the trench with a metal, and polishing the metal film by a CMP method so as to leave a metal pattern in the trench.

### BACKGROUND

### Field of the Technology

The present disclosure relates to a manufacturing method for a semiconductor device.

### Description of the Related Art

A damascene method is known as a method of forming a metal pattern on a substrate. In the damascene method, a wiring trench is formed in an interlayer dielectric film, a metal film is formed on the interlayer dielectric film so as to fill the wiring trench with a metal, and the metal film other than that in the wiring trench is then removed by a CMP method. For example, this method has a disadvantage that dishing occurs in the surface of an interlayer dielectric film or has a limitation that vacuum processes are required for the formation and processing of an interlayer dielectric film or a limitation that the choices of materials are limited.

### SUMMARY

The present disclosure provides a novel technique for forming a metal pattern on a substrate.

The present disclosure includes a manufacturing method for a semiconductor device, the method comprising: forming a depression in an interlayer dielectric film placed on a semiconductor substrate; forming a planarized film made of a first cured product of a first curable composition on the interlayer dielectric film so as to cover the depression; forming, on the planarized film, a pattern made of a second cured product of a second curable composition and having an opening on the depression; etching the planarized film by using the pattern so as to form a trench in the first cured product in the depression; forming a metal film on the interlayer dielectric film so as to fill the trench with a metal; and polishing the metal film by a CMP method so as to leave a metal pattern in the trench.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the arrangement of a planarization apparatus;

FIG. 2 is a view schematically showing the arrangement of an imprint apparatus;

FIG. 3 is a view schematically showing a sectional arrangement of a semiconductor device according to the first embodiment;

FIG. 4 is a view schematically showing a sectional arrangement of the semiconductor device according to the first embodiment;

FIG. 5 is a view showing the first example of a manufacturing method for the semiconductor device according to the first embodiment;

FIG. 6 is a view showing the first example of the manufacturing method for the semiconductor device according to the first embodiment;

FIG. 7 is a view showing the first example of the manufacturing method for the semiconductor device according to the first embodiment;

FIG. 8 is a view showing the second example of the manufacturing method for the semiconductor device according to the first embodiment;

FIG. 9 is a view showing the second example of the manufacturing method for the semiconductor device according to the first embodiment;

FIG. 10 is a view showing the second example of the manufacturing method for the semiconductor device according to the first embodiment;

FIG. 11 is a view showing the third example of the manufacturing method for the semiconductor device according to the first embodiment;

FIG. 12 is a view showing the third example of the manufacturing method for the semiconductor device according to the first embodiment;

FIG. 13 is a view showing the fourth example of the manufacturing method for the semiconductor device according to the first embodiment;

FIG. 14 is a view showing the fourth example of the manufacturing method for the semiconductor device according to the first embodiment;

FIG. 15 is a view schematically showing a sectional arrangement of a semiconductor device according to the second embodiment;

FIG. 16 is a view showing the first example of the manufacturing method for the semiconductor device according to the second embodiment;

FIG. 17 is a view showing the first example of the manufacturing method for the semiconductor device according to the second embodiment; and

FIG. 18 is a view showing the second example of a manufacturing method for the semiconductor device according to the second embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

Before a description of a manufacturing method for a semiconductor device according to the present embodiment, a planarization apparatus and an imprint apparatus which can be used in the manufacturing method will be exemplarily described first. The planarization apparatus and the imprint apparatus each is an apparatus that forms a film made of a cured product of a curable composition by applying curing energy to the curable composition arranged on a substrate. A curable composition is a composition to be cured by receiving curing energy. As the curing energy, an electromagnetic wave, heat, or the like can be used. The electromagnetic wave can be, for example, light selected from the wavelength range of 10 nm (inclusive) to 1 mm (inclusive), such as infrared rays, visible light, or ultraviolet light. The curable composition may be understood as a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable composition can be arranged on the substrate in the form of droplets or in the form of an island or film formed by connecting a plurality of droplets. Alternatively, the curable composition may be supplied onto the substrate in the form of a film by a spin coater or a slit coater. The viscosity (the viscosity at 25° C.) of an imprint material can be, for example, from 1 mPa·s (inclusive) to 100 mPa·s (inclusive).

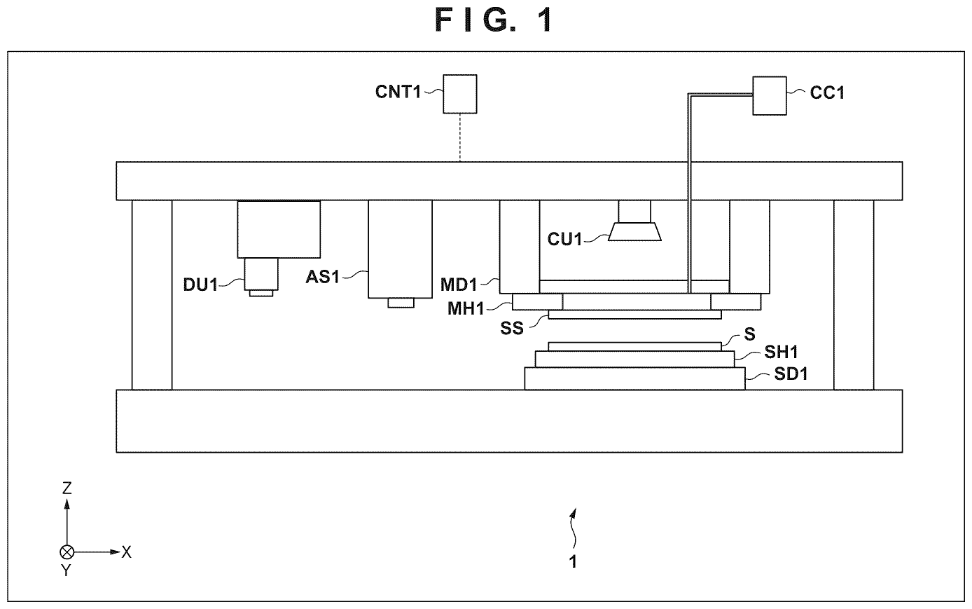

FIG. 1 schematically shows the arrangement of a planarization apparatus 1. The planarization apparatus 1 can include a substrate holder SH1 that holds the substrate S, and a substrate driving mechanism SD1 that drives the substrate S by driving the substrate holder SH1. The substrate driving mechanism SD1 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The planarization apparatus 1 can include a mold holder MH1 that holds superstrate SS as a mold having a surface to be planarized and a mold driving mechanism MD1 that drives the superstrate SS by driving the mold holder MH1. The mold driving mechanism MD1 can be configured to drive the superstrate SS with respect to a plurality of axes (for example, three axes including the Z-axis, θX-axis, and θY-axis, and preferably six axes including the X-axis, Y-axis, Z-axis, θX-axis, θY-axis, and θZ-axis).

The planarization apparatus 1 can also include the shape controller CC1 that controls the shape related to the Z-axis of the superstrate SS held by the mold holder MH1. For example, the shape controller CC1 can control the shape related to the Z-axis of the superstrate SS by adjusting the pressure on the rear surface (the surface on the opposite side of the surface including the pattern region contacting the curable composition) of the superstrate SS held by the mold holder MH1. When bringing the pattern region of the superstrate SS into contact with the curable composition on the substrate S, the shape of the superstrate SS can normally be controlled by the shape controller CC1 so as to be convex downward.

The planarization apparatus 1 can also include a curing unit CU1 that cures the curable composition by irradiating, with curing energy, the curable composition filled into the space between the superstrate SS and the plurality of shot regions of the substrate S. In addition, the planarization apparatus 1 can include a dispenser DU1 that arranges the first curable composition on the plurality of shot regions of the substrate S. Note that the substrate S with the curable composition arranged on the plurality of shot regions may be loaded or supplied into the planarization apparatus 1. In this case, the dispenser DU1 need not be provided. The planarization apparatus 1 can include an alignment scope AS1. The alignment scope AS1 can be used to detect the position of an alignment mark provided on the substrate S.

The planarization apparatus 1 can further include a controller CNT1 that controls the substrate holder SH1, the substrate driving mechanism SD1, the mold holder MH1, the mold driving mechanism MD1, the curing unit CU1, the dispenser DU1, the alignment scope AS1, the shape controller CC1, and the like. The controller CNT1 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

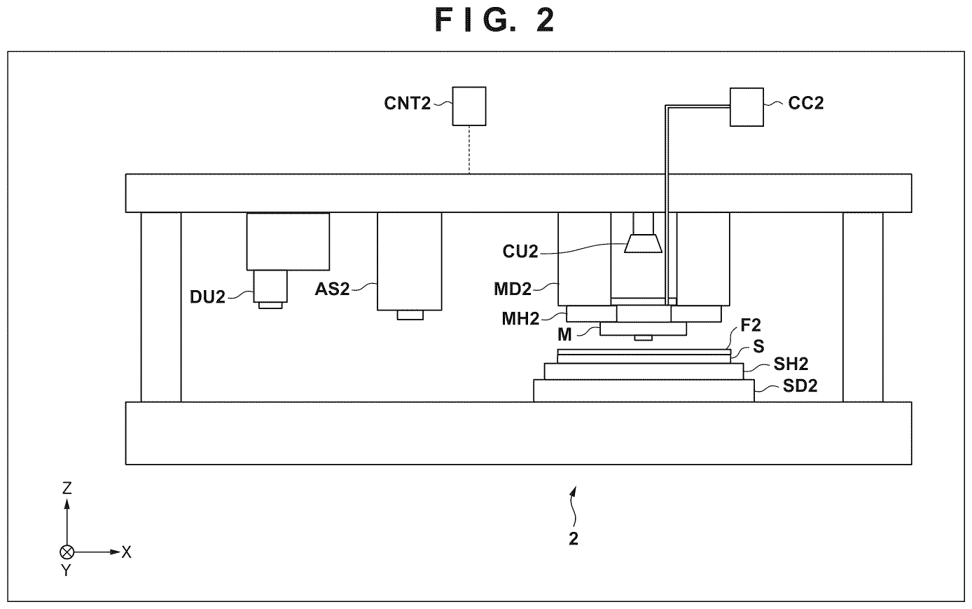

FIG. 2 schematically shows the arrangement of an imprint apparatus 2. The imprint apparatus 2 can include a substrate holder SH2 that holds the substrate S, and a substrate driving mechanism SD2 that drives the substrate S by driving the substrate holder SH2. The substrate driving mechanism SD2 can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis).

The imprint apparatus 2 can also include a mold holder MH2 that holds the mold M having a transfer surface with a three-dimensional structure to be transferred to a curable composition and a mold driving mechanism MD2 that drives the mold M by driving the mold holder MH2. The mold driving mechanism MD2 can be configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis). The imprint apparatus 2 can also include a shape controller CC2 that controls the shape related to the Z-axis of the mold M held by the mold holder MH2. For example, the shape controller CC2 can control the shape related to the Z-axis of the mold M by adjusting the pressure on the rear surface (the surface on the opposite side of the surface including the pattern region contacting the curable composition) of the mold M held by the mold holder MH2. When bringing the transfer surface of the mold M into contact with the curable composition on the substrate S, the shape of the mold M can be controlled by the shape controller CC2 so as to be convex downward.

The imprint apparatus 2 can also include a curing unit CU2 that cures the curable composition by irradiating, with curing energy, the curable composition filled into the space between the mold M and the shot region of the substrate S. In addition, the imprint apparatus 2 can include a dispenser DU2 that arranges the second curable composition on the shot region of the substrate S. Note that the substrate S with the curable composition arranged on the plurality of shot regions may be loaded or supplied into the imprint apparatus 2. In this case, the dispenser DU2 need not be provided. The imprint apparatus 2 can include an alignment scope AS2. The alignment scope AS2 can be used to detect the position of an alignment mark provided on the substrate S.

The imprint apparatus 2 can further include a controller CNT2 that controls the substrate holder SH2, the substrate driving mechanism SD2, the mold holder MH2, the mold driving mechanism MD2, the curing unit CU2, the dispenser DU2, the alignment scope AS2, the shape controller CC2, and the like. The controller CNT2 can be formed by, for example, a PLD (an abbreviation of Programmable Logic Device) such as an FPGA (an abbreviation of Field Programmable Gate Array), an ASIC (an abbreviation of Application Specific Integrated Circuit), a general-purpose or dedicated computer installed with a program, or a combination of all or some of them.

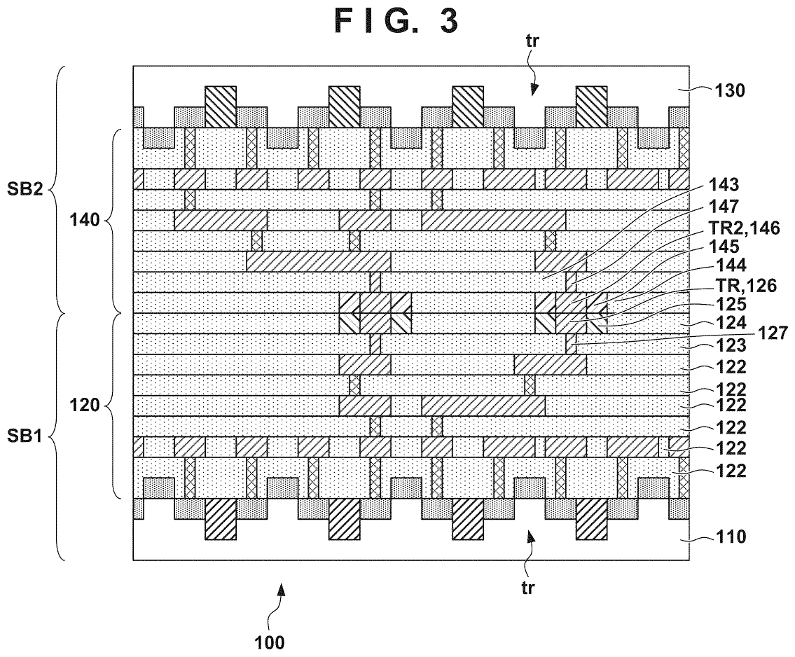

FIG. 3 schematically shows a sectional arrangement of a semiconductor device 100 according to the first embodiment. The semiconductor device 100 can include an interlayer dielectric film 124 including a cured product 125 of the curable composition placed on a semiconductor substrate 110, a trench TR provided in the cured product 125, and a metal pattern 126 filled in the trench TR. The cured product 125 can be formed by using the planarization apparatus 1 and the imprint apparatus 2. Alternatively, the cured product 125 can be formed by using the imprint apparatus 2. A curable composition can be a photo-curable composition. The interlayer dielectric film 124 may further include an inorganic insulating film having a depression. The cured product 125 can be placed in the depression. The inorganic insulating film can include, for example, at least one of a phospho silicate glass (PSG) film, a boron phospho silicate glass (BPSG) film, and a spin on glass (SOG) film. Alternatively, the inorganic insulating film can include at least one of an SiN film, an SiO₂ film, and an SiON film.

Although not shown in FIG. 3, the overall interlayer dielectric film 124 may be formed of the cured product 125. The semiconductor device 100 can further include a via plug 127 connected to the metal pattern 126. The via plug 127 can be placed on an interlayer dielectric film 123 placed between the interlayer dielectric film 124 and the semiconductor substrate 110. The metal pattern 126 and the via plug 127 may be individually formed by, for example, a single damascene method or may be integrally formed by, for example, a dual damascene method. A barrier metal (not shown) can be placed between the trench TR and the metal pattern 126. The barrier metal can be formed from, for example, Ta, TaN, or TiN. The metal pattern 126 can be formed from, for example, copper or an alloy containing copper as a main component.

In one aspect, the semiconductor device 100 can include a substrate SB1 including the semiconductor substrate 110 and a wiring structure 120. The wiring structure 120 can include the interlayer dielectric film 124. Alternatively, the wiring structure 120 can include the interlayer dielectric films 124 and 123. Alternatively, the wiring structure 120 can include at least one interlayer dielectric film 122 in addition to the interlayer dielectric films 124 and 123. The interlayer dielectric film 122 can be placed between the interlayer dielectric film 123 and the semiconductor substrate 110. A plurality of transistors Tr can be arranged on the semiconductor substrate 110.

The interlayer dielectric films 122 and 123 each can be formed of, for example, an inorganic material film. The inorganic material film can include, for example, at least one of a PSG film, a BPSG film, an SOG film, an SiN film, an SiO₂ film, and an SiON film. Alternatively, the interlayer dielectric films 122 and 123 each may be formed of an organic material film.

In another aspect, the semiconductor device 100 can include a multilayer structure including a substrate SB1 as the first substrate including the semiconductor substrate 110 and the wiring structure 120 and a substrate SB2 as the second substrate including a semiconductor substrate 130 and a wiring structure 140. In still another aspect, the semiconductor device 100 is a semiconductor device including the substrate SB1 as the first substrate and the substrate SB2 as the second substrate. The semiconductor device 100 may further include one or more other substrates. The substrate SB1 can have the metal pattern 126 as the first metal pattern. The substrate SB2 can have a metal pattern 146 as the second metal pattern. The semiconductor device 100 can have a structure having the metal pattern 126 joined to the metal pattern 146.

The substrate SB2 can include an interlayer dielectric film 144 including a cured product 145 of the curable composition placed on the semiconductor substrate 130, a trench TR2 provided in the cured product 145, and the metal pattern 146 filled in the trench TR2. The cured product 145 can be formed by using the planarization apparatus 1 and the imprint apparatus 2. Alternatively, the cured product 145 can be formed by using the imprint apparatus 2. A curable composition can be a photo-curable composition. The interlayer dielectric film 144 may further include an inorganic insulating film having a depression. The cured product 145 can be placed in the depression. The inorganic insulating film can include, for example, at least one of a PSG film, a BPSG film, an SOG film, an SiN film, an SiO₂ film, and an SiON film.

Although not shown in FIG. 3, the overall interlayer dielectric film 144 may be formed of the cured product 145. In another example, the overall interlayer dielectric film 144 may be formed of an inorganic insulating film. The substrate SB2 can further include a via plug 147 connected to the metal pattern 146. The via plug 147 can be placed on the interlayer dielectric film 143 placed between the interlayer dielectric film 144 and the semiconductor substrate 130. The metal pattern 146 and the via plug 147 may be individually formed by, for example, a single damascene method or may be integrally formed by, for example, a dual damascene method. A barrier metal (not shown) can be placed between the trench TR2 and the metal pattern 146. The barrier metal can be formed from, for example, Ta, TaN, or TiN. The metal pattern 146 can be formed from, for example, copper or an alloy containing copper as a main component.

In a case where the metal pattern 126 is placed on the uppermost surface of the substrate SB1, and the metal pattern 146 is placed on the uppermost surface of the substrate SB2, the metal pattern 126 can be joined to the metal pattern 146. In this case, the metal pattern 126 and the metal pattern 146 can be directly joined to each other without passing through another material or can be joined to each other through a conductive material.

The semiconductor substrates 110 and 130 each can be a silicon substrate, SiC substrate, or GaN substrate but are not limited to this.

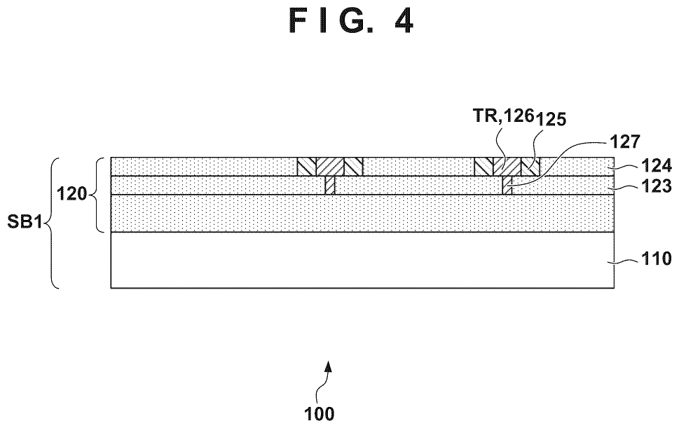

FIG. 4 shows a sectional arrangement of part of the semiconductor device 100 shown in FIG. 3. The semiconductor device 100 can include the semiconductor substrate 110 and the wiring structure 120 placed on the semiconductor substrate 110. The wiring structure 120 can include the interlayer dielectric film 124 including the cured product 125 of the curable composition placed on the semiconductor substrate 110. The wiring structure 120 can include the interlayer dielectric film 123 placed between the semiconductor substrate 110 and the interlayer dielectric film 124. The wiring structure 120 can include one or a plurality of interlayer dielectric films placed between the semiconductor substrate 110 and the interlayer dielectric film 123.

The wiring structure 120 can include the trench TR provided in the cured product 125 and the metal pattern 126 filled in the trench TR. The cured product 125 can be formed by using the planarization apparatus 1 and the imprint apparatus 2. Alternatively, the cured product 125 can be formed by using the imprint apparatus 2. A curable composition can be a photo-curable composition. The interlayer dielectric film 124 may further include an inorganic insulating film having a depression. The cured product 125 can be placed in the depression. The semiconductor device 100 can further include the via plug 127 connected to the metal pattern 126. The via plug 127 can be placed on the interlayer dielectric film 123. The metal pattern 126 and the via plug 127 may be individually formed by, for example, a single damascene method or may be integrally formed by, for example, a dual damascene method. A barrier metal (not shown) can be placed between the trench TR and the metal pattern 126. The barrier metal can be formed from, for example, Ta, TaN, or TiN.

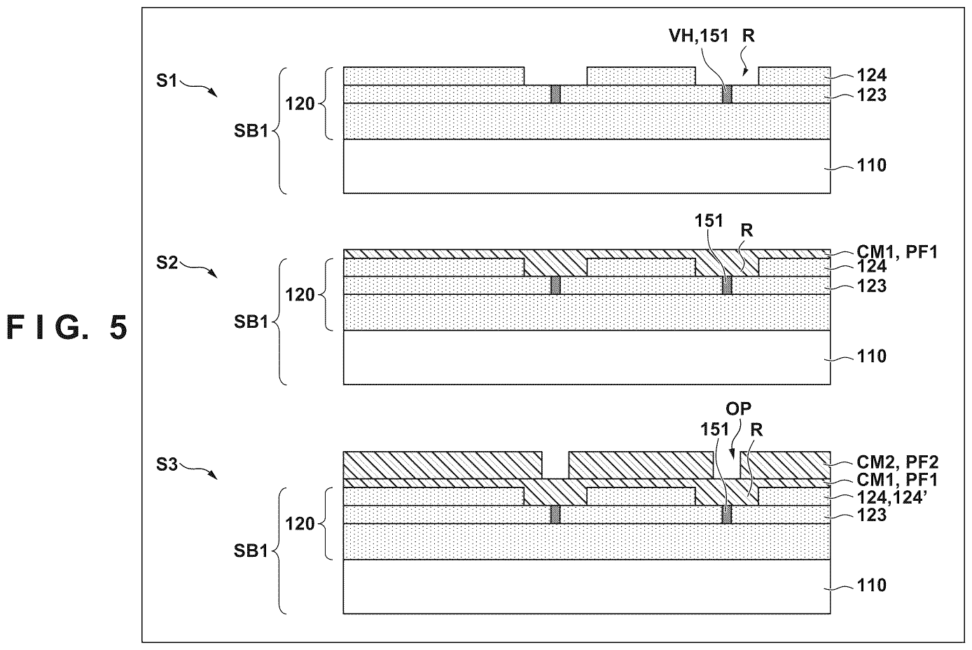

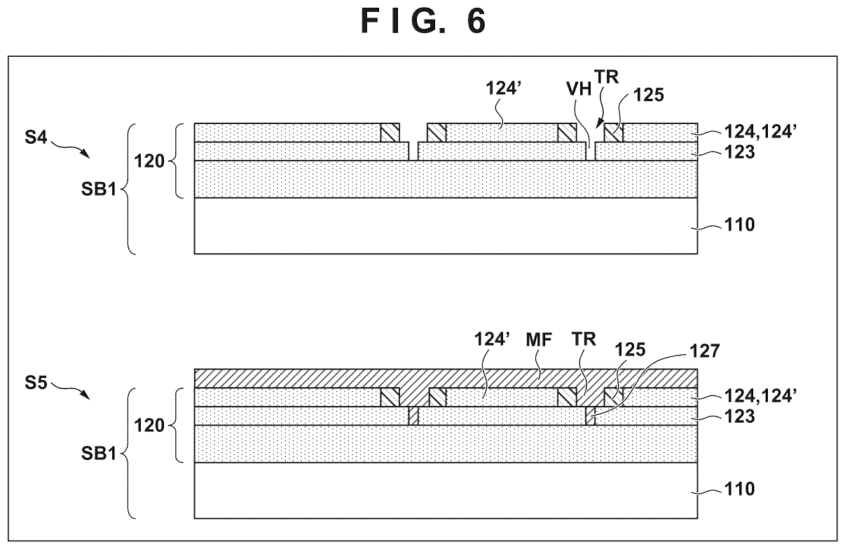

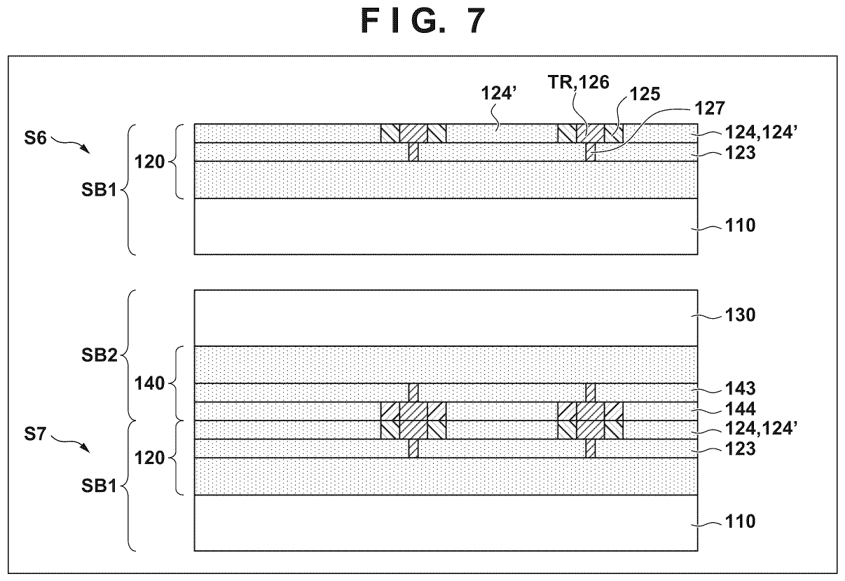

The first example of a manufacturing method for the semiconductor device 100 according to the first embodiment shown in FIGS. 3 and 4 will be exemplarily described below with reference to FIGS. 5, 6, and 7. Note that an application example of the dual damascene method will be described below. In step S1, for example, a via hole VH is formed by a lithography step in the interlayer dielectric film 123 formed of an inorganic insulating film. The lithography step may include, for example, a photolithography step using a projection exposure apparatus or an imprint step using an imprint apparatus. The same applies to the lithography step described below. A dummy plug 151 may be formed by filling the via hole VH with a filling material as needed. The interlayer dielectric film 124 can be formed on the interlayer dielectric film 123. In this stage, the interlayer dielectric films 123 and 124 each can include at least one of, for example, a PSG film, a BPSG film, an SOG film, an SiN film, an SiO₂ film, and an SiON film. A depression R can then be formed in the interlayer dielectric film 124 by a lithography step (depression forming step). That is, step S1 can include a depression forming step of forming the depression R in the interlayer dielectric film 124 placed on the semiconductor substrate 110. Note that the interlayer dielectric film 124 in which the depression R is formed is also written as an interlayer dielectric film 124′. In the subsequent steps, the interlayer dielectric film 124 becomes an interlayer dielectric film including the cured product 125 in addition to the interlayer dielectric film 124′.

Subsequently, in step S2, a planarization step can be executed to form a planarized film PF1 made of the first cured product of a first curable composition CM1 on the interlayer dielectric film 124 so as to cover the depression R. The planarization step can be executed by using the planarization apparatus 1. That is, in the planarization step, the planarized film PF1 can be formed by placing a first curable composition CM1 on the interlayer dielectric film 124, bringing the superstrate SS into contact with the first curable composition CM1, and curing the first curable composition CM1. Note that in step S1, the dummy plug 151 may be formed as part of the planarized film PF1 by filling the via hole VH with the curable composition CM1 and curing the curable composition CM1 in a planarization step without filling the via hole VH with a filling material in step S1.

In step S3, a pattern forming step can be executed to form, on the planarized film PF1, a pattern PF2 made of the second cured product of a second curable composition CM2 and having an opening OP in the depression R. The pattern forming step can be executed by using the imprint apparatus 2. That is, in the pattern forming step, the pattern PF2 can be formed by placing the second curable composition CM2 on the planarized film PF1, bringing the mold M into contact with the second curable composition CM2, and curing the second curable composition CM2. The composition of the second curable composition CM2 may be the same as or different from that of the first curable composition CM1.

In step S4, an etching step can be executed to etch the planarized film PF1 by using the pattern PF2 so as to form the trench TR in the first cured product (part of the planarized film PF) in the depression R. In this etching step, the planarized film PF1 is etched in accordance with the shape of the pattern PF2 having the opening OP, and the first cured product (part of the planarized film PF) can be left as the cured product 125 having the trench TR. At this point of time, the interlayer dielectric film 124 is formed by the interlayer dielectric film 124′ and the cured product 125. In addition, the dummy plug 151 can be removed by etching.

In step S5, a metal film forming step is executed to form the metal film MF on the interlayer dielectric film 124 so as to fill the via hole VH and the trench TR with a metal. Although not shown, before the metal film forming step, a barrier metal can be formed so as to cover the bottom surface and side surface of the via hole VH, the bottom surface and side surface of the trench TR, and the upper surface of the interlayer dielectric film 124. The barrier metal can be formed from, for example, Ta, TaN, or TiN. The barrier metal can be formed by, for example, a sputter method or CVD method. After the barrier metal is formed, the metal film MF can be formed by a plating method. The metal film MF can be formed from, for example, copper or an alloy containing copper as a main component.

In step S6, a polishing step can be executed to polish the metal film MF by a chemical mechanical polishing (CMP) method so as to leave the metal pattern 126 in the via hole VH and the trench TR. In other words, in step S6, a polishing step can be executed to polish the metal film MF by the CMP method so as to form the metal pattern 126 in the via hole VH and the trench TR. A slurry can be prepared to make the polishing rate of the cured product 125 (the first cured product) in the polishing step become lower than that of the interlayer dielectric film 124′ in the polishing step. Through the polishing step, the semiconductor substrate 130 or the semiconductor device 100 is obtained.

In step S7, the substrate SB2 as the second substrate can be joined to the substrate SB1 as the first substrate. Subsequently, another or other substrates may be joined to the substrate SB1 or the substrate SB2.

In one aspect, a manufacturing method for the semiconductor device 100 can include the first preparation step (S1 to S6) of preparing the substrate SB1 as the first substrate having the metal pattern 126 as the first metal pattern. The manufacturing method for the semiconductor device 100 can also include the second preparation step of preparing the substrate SB2 as the second substrate having the metal pattern 146 as the second metal pattern. The second preparation step can be a step similar to the first preparation step but may be a step different from the first preparation step. The manufacturing method for the semiconductor device 100 can also include a joining step (S7) of obtaining the semiconductor device 100 including the substrate SB1 and the substrate SB2 by joining the metal pattern 126 to the metal pattern 146.

In another example, the semiconductor device 100 may be completed without joining the substrate SB2 to the substrate SB1.

The above is an application example of the dual damascene method. However, a conductive plug may be formed instead of the dummy plug 151 and may be used as a via plug without being removed in step S4. Such a method is called a single damascene method.

According to the first example, letting the interlayer dielectric film 124 have the cured product 125 surrounding the metal pattern 126 can reduce dishing in a CMP step as compared with a case where the interlayer dielectric film 124 does not have the cured product 125. This makes it possible to leave the interlayer dielectric film 124 having a flat surface after the CMP step. The interlayer dielectric film 124 having a flat surface is advantageous in joining the substrate SB2 to the interlayer dielectric film 124.

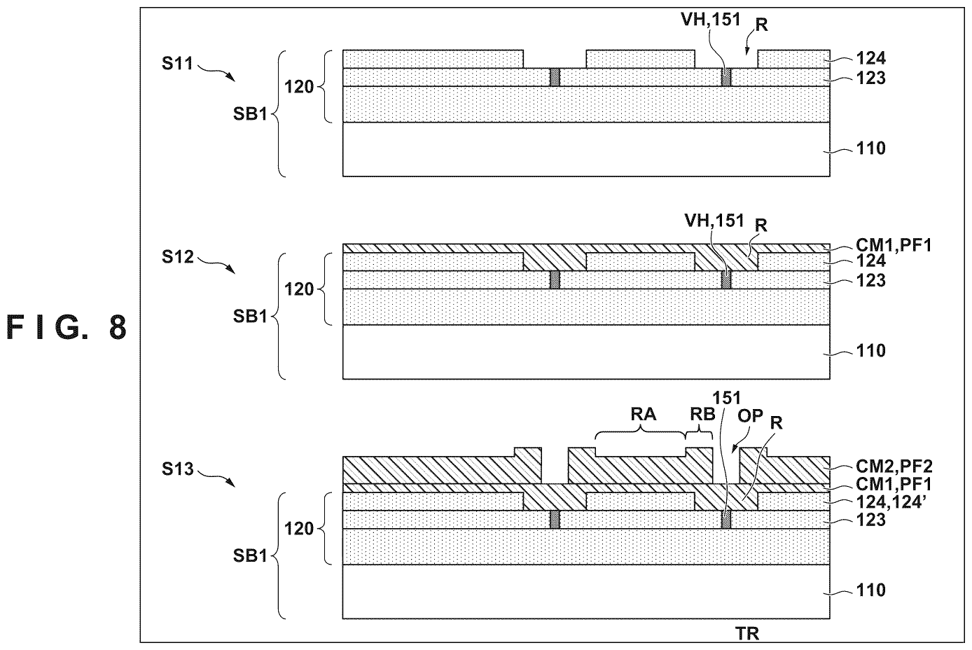

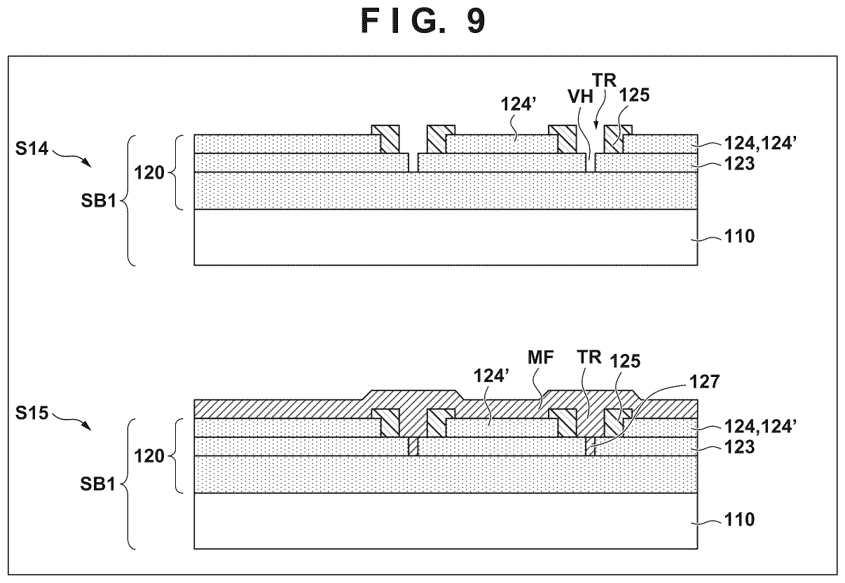

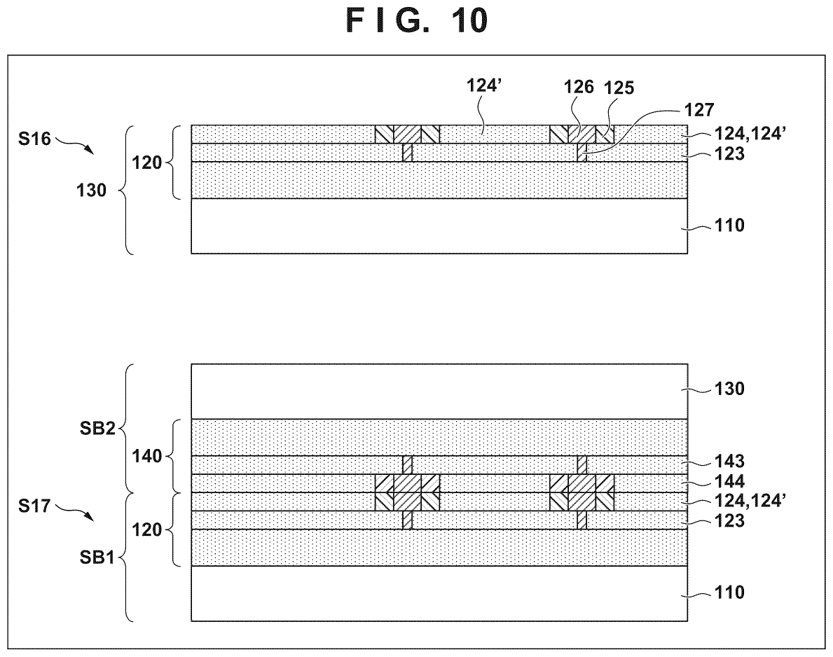

The second example of the manufacturing method for the semiconductor device 100 shown in FIGS. 3 and 4 will be exemplarily described below with reference to FIGS. 8, 9, and 10. Note that an application example of the dual damascene method will be described below. In step S11, for example, a via hole VH is formed by a lithography step in the interlayer dielectric film 123 formed of an inorganic insulating film. A dummy plug 151 may then be formed by filling the via hole VH with a filling material as needed. The interlayer dielectric film 124 can be formed on the interlayer dielectric film 123. In this stage, the interlayer dielectric films 123 and 124 each can include at least one of, for example, a PSG film, a BPSG film, an SOG film, an SiN film, an SiO₂ film, and an SiON film. A depression R can then be formed in the interlayer dielectric film 124 by a lithography step (depression forming step). That is, step S1 can include a depression forming step of forming the depression R in the interlayer dielectric film 124 placed on the semiconductor substrate 110. Note that the interlayer dielectric film 124 in which the depression R is formed is also written as an interlayer dielectric film 124′. In the subsequent steps, the interlayer dielectric film 124 becomes an interlayer dielectric film including the cured product 125 in addition to the interlayer dielectric film 124′.

Subsequently, in step S12, a planarization step can be executed to form a planarized film PF1 made of the first cured product of a first curable composition CM1 on the interlayer dielectric film 124 so as to cover the depression R. The planarization step can be executed by using the planarization apparatus 1. That is, in the planarization step, the planarized film PF1 can be formed by placing a first curable composition CM1 on the interlayer dielectric film 124, bringing the superstrate SS into contact with the first curable composition CM1, and curing the first curable composition CM1. Note that the dummy plug 151 may be formed as part of the planarized film PF1 by filling the via hole VH with the curable composition CM1 and curing the curable composition CM1 in a planarization step without filling the via hole VH with a filling material in step S11.

In step S13, a pattern forming step can be executed to form, on the planarized film PF1, a pattern PF2 made of the second cured product of a second curable composition CM2 and having an opening OP in the depression R. The pattern forming step can be executed by using the imprint apparatus 2. That is, in the pattern forming step, the pattern PF2 can be formed by placing the second curable composition CM2 on the planarized film PF1, bringing the mold M into contact with the second curable composition CM2, and curing the second curable composition CM2. The composition of the second curable composition CM2 may be the same as or different from that of the first curable composition CM1. In the second example, in the pattern forming step, the pattern PF2 can be formed so as to have a first region RA having the first height and a second region RB placed between the first region RA and the opening OP and having the second height higher than the first height.

In step S14, an etching step can be executed to etch the planarized film PF1 by using the pattern PF2 so as to form the trench TR in the first cured product (part of the planarized film PF) in the depression R. In this etching step, the planarized film PF1 is etched in accordance with the shape of the pattern PF2 having the opening OP, and the first cured produce (part of the planarized film PF) can be left as the cured product 125 having the trench TR. At this point of time, the interlayer dielectric film 124 is formed by the interlayer dielectric film 124′ and the cured product 125. In addition, the dummy plug 151 can be removed by etching. In the second example, the upper surface of the cured product 125 is higher than the upper surface of the interlayer dielectric film 124′. This is the result obtained by the reflection of the first region RA having the first height and the second region RB having the second height higher than the first height.

In step S15, a metal film forming step is executed to form the metal film MF on the interlayer dielectric film 124 so as to fill the via hole VH and the trench TR with a metal. Although not shown, before the metal film forming step, a barrier metal can be formed so as to cover the bottom surface and side surface of the via hole VH, the bottom surface and side surface of the trench TR, and the upper surface of the interlayer dielectric film 124. The barrier metal can be formed from, for example, Ta, TaN, or TiN. The barrier metal can be formed by, for example, a sputter method or CVD method. After the barrier metal is formed, the metal film MF can be formed by a plating method. The metal film MF can be formed from, for example, copper or an alloy containing copper as a main component.

In step S16, a polishing step can be executed to polish the metal film MF by the CMP method so as to leave the metal pattern 126 in the via hole VH and the trench TR. In other words, in step S16, a polishing step can be executed to polish the metal film MF by the CMP method so as to form the metal pattern 126 in the via hole VH and the trench TR. A slurry can be prepared to make the polishing rate of the cured product 125 (the first cured product) in the polishing step become lower than that of the interlayer dielectric film 124′ in the polishing step. Through the polishing step, the semiconductor substrate 130 or the semiconductor device 100 is obtained.

In step S17, the substrate SB2 as the second substrate can be joined to the substrate SB1 as the first substrate. Subsequently, another or other substrates may be joined to the substrate SB1 or the substrate SB2.

In one aspect, a manufacturing method for the semiconductor device 100 can include the first preparation step (S11 to S16) of preparing the substrate SB1 as the first substrate having the metal pattern 126 as the first metal pattern. The manufacturing method for the semiconductor device 100 can also include the second preparation step of preparing the substrate SB2 as the second substrate having the metal pattern 146 as the second metal pattern. The second preparation step can be a step similar to the first preparation step but may be a step different from the first preparation step. The manufacturing method for the semiconductor device 100 can also include a joining step (S17) of obtaining the semiconductor device 100 including the substrate SB1 and the substrate SB2 by joining the metal pattern 126 to the metal pattern 146.

In another example, the semiconductor device 100 may be completed without joining the substrate SB2 to the substrate SB1.

The above is an application example of the dual damascene method. However, a conductive plug may be formed instead of the dummy plug 151 and may be used as a via plug without being removed in step S14. Such a method is called a single damascene method.

According to the second example, since the upper surface of the cured product 125 is higher than the upper surface of the interlayer dielectric film 124′ before the execution of the CMP step, it is possible to reduce dishing in the CMP step as compared with the first example. This makes it possible to leave the interlayer dielectric film 124 having a flatter surface after the CMP step. The interlayer dielectric film 124 having a flat surface is advantageous in joining the substrate SB2 to the interlayer dielectric film 124.

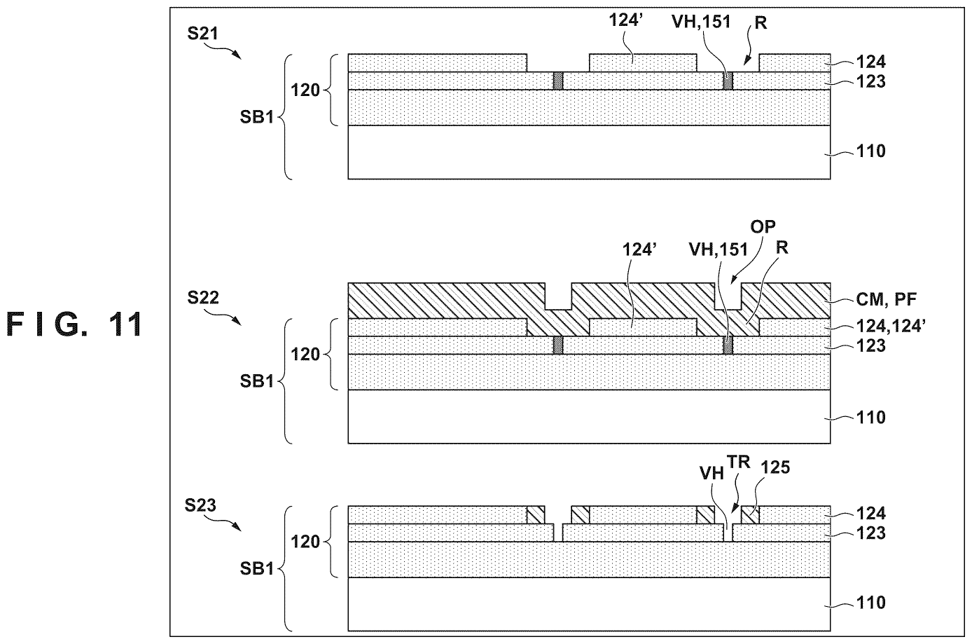

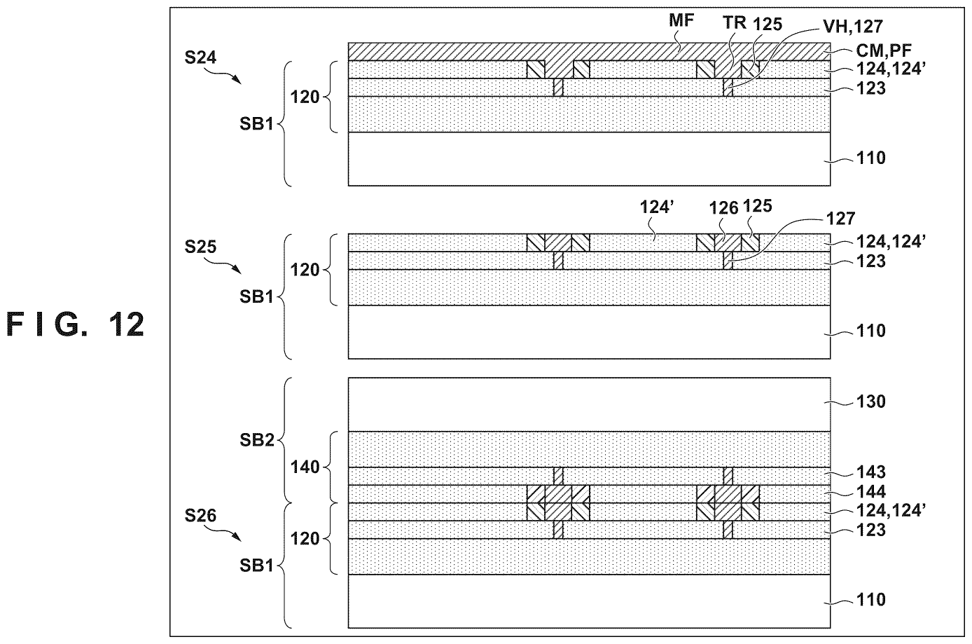

The third example of the manufacturing method for the semiconductor device 100 shown in FIGS. 3 and 4 will be exemplarily described below with reference to FIGS. 11 and 12. Note that an application example of the dual damascene method will be described below. In step S21, for example, a via hole VH is formed by a lithography step in the interlayer dielectric film 123 formed of an inorganic insulating film. A dummy plug 151 may then be formed by filling the via hole VH with a filling material as needed. The interlayer dielectric film 124 can be formed on the interlayer dielectric film 123. In this stage, the interlayer dielectric films 123 and 124 each can include at least one of, for example, a PSG film, a BPSG film, an SOG film, an SiN film, an SiO₂ film, and an SiON film. A depression R can then be formed in the interlayer dielectric film 124 by a lithography step (depression forming step). That is, step S21 can include a depression forming step of forming the depression R in the interlayer dielectric film 124 placed on the semiconductor substrate 110. Note that the interlayer dielectric film 124 in which the depression R is formed is also written as an interlayer dielectric film 124′. In the subsequent steps, the interlayer dielectric film 124 becomes an interlayer dielectric film including the cured product 125 in addition to the interlayer dielectric film 124′.

Subsequently, in step S22, a pattern forming step can be executed to form, on the interlayer dielectric film 124, the pattern PF which is formed of the cured product of the curable composition CM so as to cover the depression R and has the opening OP. The pattern forming step can be executed by using the imprint apparatus 2. That is, in the pattern forming step, the pattern PF can be formed by placing the curable composition CM on the interlayer dielectric film 124, bringing the mold M into contact with the curable composition, and curing the curable composition. Note that the dummy plug 151 may be formed as part of the pattern PF by filling the via hole VH with the curable composition CM and curing the curable composition CM in the pattern forming step without filling the via hole VH with a filling material in step S21.

Subsequently, in step S23, an etching step can be executed to etch the overall planarized film PF so as to form the trench TR in the cured product (part of the planarized film PF) in the depression R. In this etching step, the thickness of the pattern PF can decrease, and the cured product in the depression R (part of the planarized film PF) can remain as the cured product 125 having the trench TR. At this point of time, the interlayer dielectric film 124 is formed by the interlayer dielectric film 124′ and the cured product 125. In addition, the dummy plug 151 can be removed by etching.

In step S24, a metal film forming step is executed to form the metal film MF on the interlayer dielectric film 124 so as to fill the via hole VH and the trench TR with a metal. Although not shown, before the metal film forming step, a barrier metal can be formed so as to cover the bottom surface and side surface of the via hole VH, the bottom surface and side surface of the trench TR, and the upper surface of the interlayer dielectric film 124. The barrier metal can be formed from, for example, Ta, TaN, or TiN. The barrier metal can be formed by, for example, a sputter method or CVD method. After the barrier metal is formed, the metal film MF can be formed by a plating method. The metal film MF can be formed from, for example, copper or an alloy containing copper as a main component.

In step S25, a polishing step can be executed to polish the metal film MF by the CMP method so as to leave the metal pattern 126 in the via hole VH and the trench TR. In other words, in step S25, a polishing step can be executed to polish the metal film MF by the CMP method so as to form the metal pattern 126 in the via hole VH and the trench TR. A slurry can be prepared to make the polishing rate of the cured product 125 in the polishing step become lower than that of the interlayer dielectric film 124′ in the polishing step. Through the polishing step, the semiconductor substrate 130 or the semiconductor device 100 is obtained.

In step S26, the substrate SB2 as the second substrate can be joined to the substrate SB1 as the first substrate. Subsequently, another or other substrates may be joined to the substrate SB1 or the substrate SB2.

In one aspect, a manufacturing method for the semiconductor device 100 can include the first preparation step (S21 to S25) of preparing the substrate SB1 as the first substrate having the metal pattern 126 as the first metal pattern. The manufacturing method for the semiconductor device 100 can also include the second preparation step of preparing the substrate SB2 as the second substrate having the metal pattern 146 as the second metal pattern. The second preparation step can be a step similar to the first preparation step but may be a step different from the first preparation step. The manufacturing method for the semiconductor device 100 can also include a joining step (S26) of obtaining the semiconductor device 100 including the substrate SB1 and the substrate SB2 by joining the metal pattern 126 and the metal pattern 146.

In another example, the semiconductor device 100 may be completed without joining the substrate SB2 to the substrate SB1.

The above is an application example of the dual damascene method. However, a conductive plug may be formed instead of the dummy plug 151 and may be used as a via plug without being removed in step S4. Such a method is called a single damascene method.

According to the third example, letting the interlayer dielectric film 124 have the cured product 125 surrounding the metal pattern 126 can reduce dishing in the CMP step as compared with a case where the interlayer dielectric film 124 does not have the cured product 125. This makes it possible to leave the interlayer dielectric film 124 having a flat surface after the CMP step. The interlayer dielectric film 124 having a flat surface is advantageous in joining the substrate SB2 to the interlayer dielectric film 124. In addition, according to the third example, the step of forming the cured product 125 in the depression R is simplified as compared with the first example.

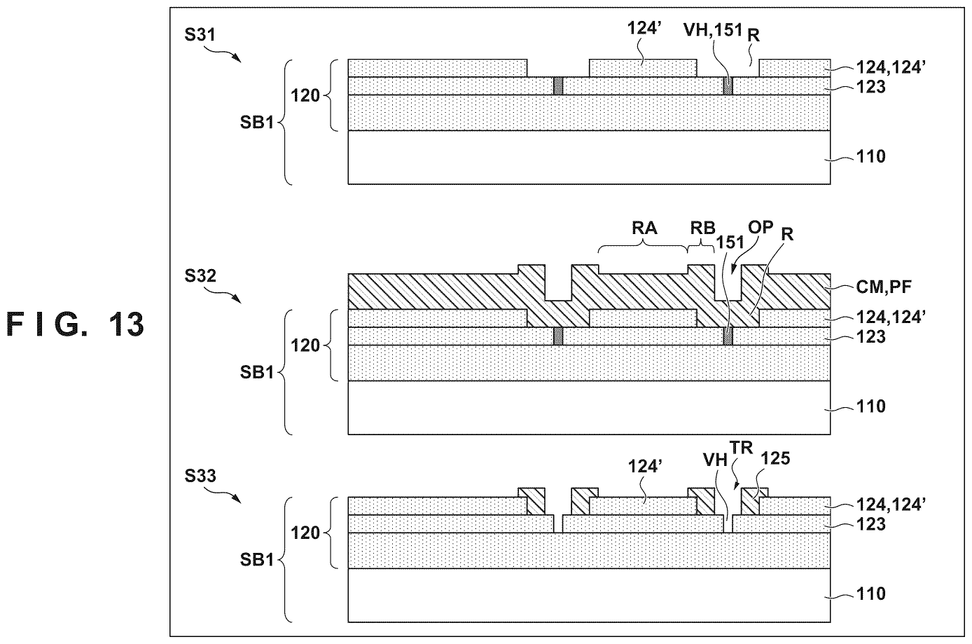

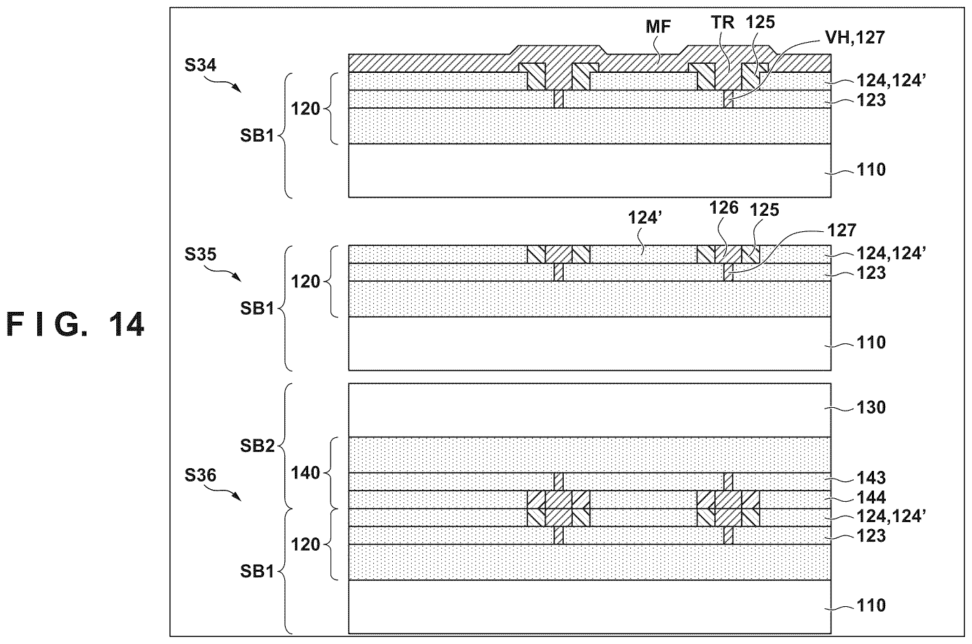

The fourth example of the manufacturing method for the semiconductor device 100 shown in FIGS. 3 and 4 will be exemplarily described below with reference to FIGS. 13 and 14. Note that an application example of the dual damascene method will be described below. In step S31, for example, a via hole VH is formed by a lithography step in the interlayer dielectric film 123 formed of an inorganic insulating film. A dummy plug 151 may then be formed by filling the via hole VH with a filling material as needed. The interlayer dielectric film 124 can be formed on the interlayer dielectric film 123. In this stage, the interlayer dielectric films 123 and 124 each can include at least one of, for example, a PSG film, a BPSG film, an SOG film, an SiN film, an SiO₂ film, and an SiON film. A depression R can then be formed in the interlayer dielectric film 124 by a lithography step (depression forming step). That is, step S31 can include a depression forming step of forming the depression R in the interlayer dielectric film 124 placed on the semiconductor substrate 110. Note that the interlayer dielectric film 124 in which the depression R is formed is also written as an interlayer dielectric film 124′. In the subsequent steps, the interlayer dielectric film 124 becomes an interlayer dielectric film including the cured product 125 in addition to the interlayer dielectric film 124′.

Subsequently, in step S32, a pattern forming step can be executed to form, on the interlayer dielectric film 124, the pattern PF which is formed of the cured product of the curable composition CM so as to cover the depression R and has the opening OP. The pattern forming step can be executed by using the imprint apparatus 2. That is, in the pattern forming step, the pattern PF can be formed by placing the curable composition CM on the interlayer dielectric film 124, bringing the mold M into contact with the curable composition, and curing the curable composition. Note that the dummy plug 151 may be formed as part of the pattern PF by filling the via hole VH with the curable composition CM and curing the curable composition CM in the pattern forming step without filling the via hole VH with a filling material in step S31. In the fourth example, in the pattern forming step, the pattern PF can be formed so as to have the first region RA having the first height and the second region RB placed between the first region RA and the opening OP and having the second height higher than the first height.

Subsequently, in step S33, an etching step can be executed to etch the overall planarized film PF so as to form the trench TR in the cured product (part of the planarized film PF) in the depression R. In this etching step, the thickness of the pattern PF can decrease, and the cured product in the depression R (part of the planarized film PF) can remain as the cured product 125 having the trench TR. At this point of time, the interlayer dielectric film 124 is formed by the interlayer dielectric film 124′ and the cured product 125. In addition, the dummy plug 151 can be removed by etching.

In step S34, a metal film forming step is executed to form the metal film MF on the interlayer dielectric film 124 so as to fill the via hole VH and the trench TR with a metal. Although not shown, before the metal film forming step, a barrier metal can be formed so as to cover the bottom surface and side surface of the via hole VH, the bottom surface and side surface of the trench TR, and the upper surface of the interlayer dielectric film 124. The barrier metal can be formed from, for example, Ta, TaN, or TiN. The barrier metal can be formed by, for example, a sputter method or CVD method. After the barrier metal is formed, the metal film MF can be formed by a plating method. The metal film MF can be formed from, for example, copper or an alloy containing copper as a main component.

In step S35, a polishing step can be executed to polish the metal film MF by the CMP method so as to leave the metal pattern 126 in the via hole VH and the trench TR. In other words, in step S35, a polishing step can be executed to polish the metal film MF by the CMP method so as to form the metal pattern 126 in the via hole VH and the trench TR. A slurry can be prepared to make the polishing rate of the cured product 125 in the polishing step become lower than that of the interlayer dielectric film 124′ in the polishing step. Through the polishing step, the semiconductor substrate 130 or the semiconductor device 100 is obtained.

In step S36, the substrate SB2 as the second substrate can be joined to the substrate SB1 as the first substrate. Subsequently, another or other substrates may be joined to the substrate SB1 or the substrate SB2.

In one aspect, a manufacturing method for the semiconductor device 100 can include the first preparation step (S31 to S35) of preparing the substrate SB1 as the first substrate having the metal pattern 126 as the first metal pattern. The manufacturing method for the semiconductor device 100 can also include the second preparation step of preparing the substrate SB2 as the second substrate having the metal pattern 146 as the second metal pattern. The second preparation step can be a step similar to the first preparation step but may be a step different from the first preparation step. The manufacturing method for the semiconductor device 100 can also include a joining step (S36) of obtaining the semiconductor device 100 including the substrate SB1 and the substrate SB2 by joining the metal pattern 126 to the metal pattern 146.

In another example, the semiconductor device 100 may be completed without joining the substrate SB2 to the substrate SB1.

The above is an application example of the dual damascene method. However, a conductive plug may be formed instead of the dummy plug 151 and may be used as a via plug without being removed in step S4. Such a method is called a single damascene method.

According to the fourth example, since the upper surface of the cured product 125 is higher than the upper surface of the interlayer dielectric film 124′ before the execution of the CMP step, it is possible to reduce dishing in the CMP step as compared with the first example. This makes it possible to leave the interlayer dielectric film 124 having a flatter surface after the CMP step. The interlayer dielectric film 124 having a flat surface is advantageous in joining the substrate SB2 to the interlayer dielectric film 124. In addition, according to the fourth example, the step of forming the cured product 125 in the depression R is simplified as compared with the second example.

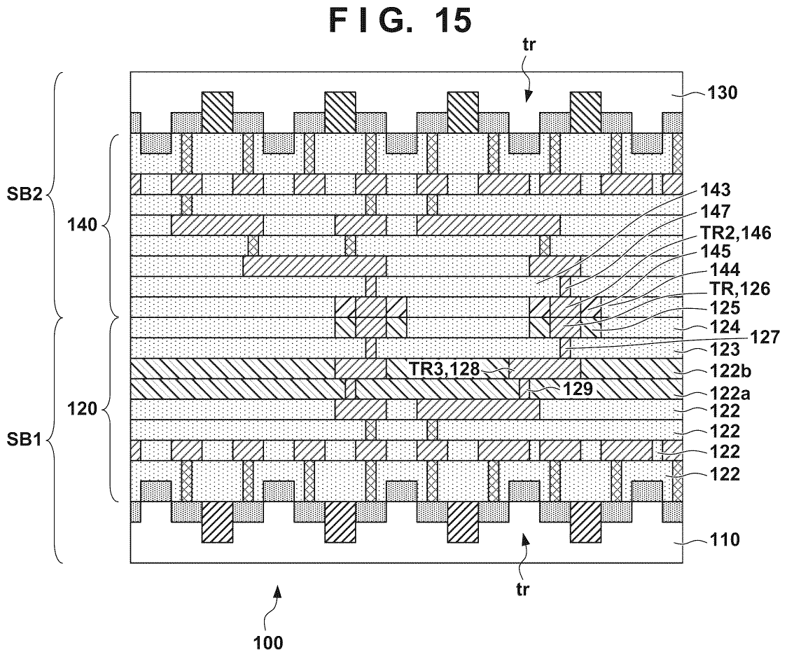

A semiconductor device 100 according to the second embodiment will be described below. Matters that are not referred to in the description of the second embodiment can comply with the description of the first embodiment, but the second embodiment may be executed independently of the first embodiment. FIG. 15 schematically shows a sectional arrangement of the semiconductor device 100 according to the second embodiment.

The semiconductor device 100 according to the second embodiment can include an interlayer dielectric film 122b including a cured product of the curable composition placed on a semiconductor substrate 110, a trench TR3 provided in an interlayer dielectric film 122b, and a metal pattern 128 filled in the trench TR3. The cured product forming the interlayer dielectric film 122b can be formed by using the planarization apparatus 1 and the imprint apparatus 2. Alternatively, a cured product 125 can be formed by using the imprint apparatus 2. A curable composition can be a photo-curable composition. An interlayer dielectric film 124 may further include an inorganic insulating film having a depression. The cured product 125 can be placed in the depression. The inorganic insulating film can include, for example, at least one of a PSG film, a BPSG film, an SOG film, an SiN film, an SiO₂ film, and an SiON film.

The overall interlayer dielectric film 122b can be formed of a cured product of the curable composition. The semiconductor device 100 can further include a via plug 129 connected to the metal pattern 128. The via plug 129 can be placed on an interlayer dielectric film 122a placed between the interlayer dielectric film 122b and the semiconductor substrate 110. The metal pattern 128 and the via plug 129 may be individually formed by, for example, a single damascene method or may be integrally formed by, for example, a dual damascene method. A barrier metal (not shown) can be placed between the trench TR3 and the metal pattern 128. The barrier metal can be formed from, for example, Ta, TaN, or TiN. A metal pattern 126 can be formed from, for example, copper or an alloy containing copper as a main component.

In one aspect, the semiconductor device 100 can include a substrate SB1 including the semiconductor substrate 110 and a wiring structure 120. The wiring structure 120 can include the interlayer dielectric film 122b. Alternatively, the wiring structure 120 can include the interlayer dielectric films 122b and 122a. Alternatively, the wiring structure 120 can include at least one interlayer dielectric film, for example, the interlayer dielectric films 122, 123, and 124 in addition to the interlayer dielectric films 122b and 122a. The interlayer dielectric film 122 is placed between the interlayer dielectric film 122a and the semiconductor substrate 110. The interlayer dielectric films 123 and 124 can be arranged on the interlayer dielectric film 122b. A plurality of transistors Tr can be arranged on the semiconductor substrate 110.

In another aspect, the semiconductor device 100 can include a multilayer structure including the substrate SB1 as the first substrate including the semiconductor substrate 110 and the wiring structure 120 and a substrate SB2 as the second substrate including a semiconductor substrate 130 and a wiring structure 140. In still another aspect, the semiconductor device 100 is a semiconductor device including the substrate SB1 as the first substrate and the substrate SB2 as the second substrate. The semiconductor device 100 may further include another or other substrates. The substrate SB1 can have the metal pattern 126 as the first metal pattern. The substrate SB2 can have a metal pattern 146 as the second metal pattern. The semiconductor device 100 can have a structure having the metal pattern 126 joined to the metal pattern 146. At least one of the interlayer dielectric films 122, 123, and 124 can be formed of, for example, an inorganic material film. The inorganic material film can include, for example, at least one of a PSG film, a BPSG film, an SOG film, an SiN film, an SiO₂ film, and an SiON film. Alternatively, the interlayer dielectric films 122 and 123 each may be formed of an organic material film.

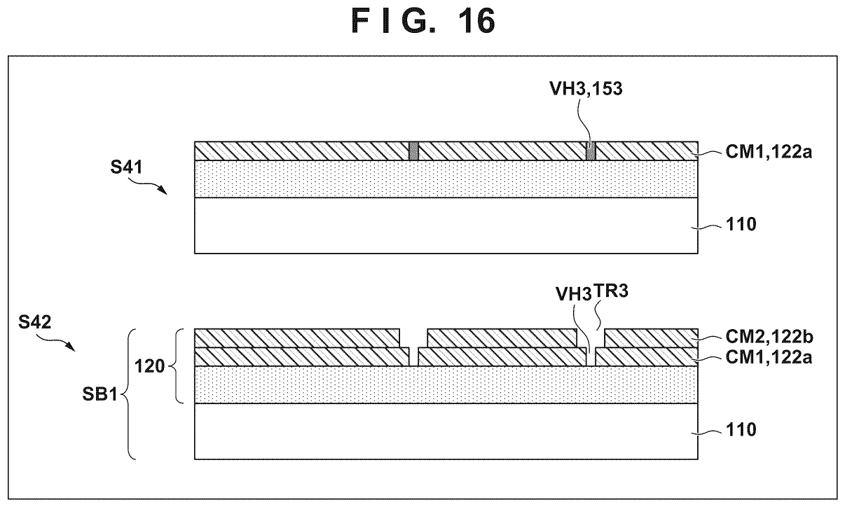

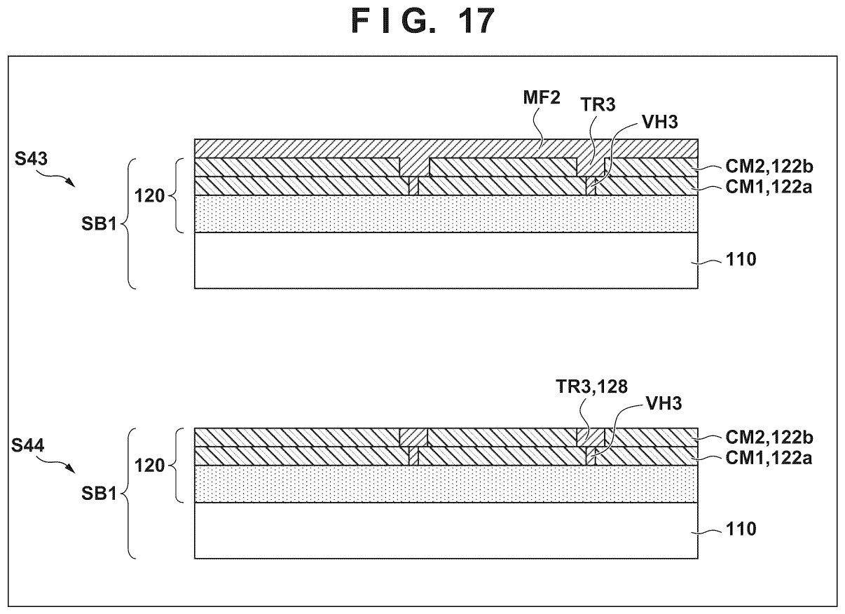

The first example of a manufacturing method for the semiconductor device 100 according to the second embodiment shown in FIG. 15 will be exemplarily described below with reference to FIGS. 16 and 17. Note that an application example of the dual damascene method will be described below. In step S41, the first insulating layer forming step can be executed to form a first interlayer dielectric film 122a as the first insulating film made of the first cured product of a first curable composition CM1 on the semiconductor substrate 110. The first insulating layer forming step can be executed by using the planarization apparatus 1. That is, in the first insulating layer forming step, the first insulating layer can be formed by placing the first curable composition CM1 on the semiconductor substrate 110, bringing the superstrate SS into contact with the first curable composition CM1, and curing the first curable composition CM1.

In addition, in step S41, a via hole VH3 can be formed in the first interlayer dielectric film 122a by a lithography step. Subsequently, a dummy plug 153 may be formed by filling the via hole VH3 with a filling material as needed.

Subsequently, in step S42, the second insulating film forming step can be executed to form, on the first interlayer dielectric film 122a, the second interlayer dielectric film 122b as the second insulating film formed of the second cured product of the second curable composition CM2 and having the trench TR3. The second insulating film forming step can be executed by using the imprint apparatus 2. That is, in the second insulating film forming step, the second interlayer dielectric film 122b can be formed as the second insulating film by placing a second curable composition CM2 on the first interlayer dielectric film 122a, bringing a mold M into contact with the second curable composition CM2, and curing the second curable composition CM2. The composition of the second curable composition CM2 may be the same as or different from that of the first curable composition CM1. The first curable composition CM1 and the second curable composition CM2 each may be a photo-curable composition. Subsequently, a dummy plug 151 can be removed by etching.

In step S43, a metal film forming step is executed to form a metal film MF2 on the second interlayer dielectric film 122b so as to fill the via hole VH3 and the trench TR3 with a metal. Although not shown, before the metal film forming step, a barrier metal can be formed so as to cover the bottom surface and side surface of the via hole VH3, the bottom surface and side surface of the trench TR3, and the upper surface of the second interlayer dielectric film 122b. The barrier metal can be formed from, for example, Ta, TaN, or TiN. The barrier metal can be formed by, for example, a sputter method or CVD method. After the barrier metal is formed, the metal film MF can be formed by a plating method. The metal film MF can be formed from, for example, copper or an alloy containing copper as a main component.

Subsequently, in step S44, a polishing step can be executed to polish the metal film MF by a CMP method so as to leave the metal pattern 126 in the via hole VH and the trench TR. In other words, in step S44, a polishing step can be executed to polish the metal film MF2 by a CMP method so as to form a metal pattern 128 placed in the via hole VH3 and the trench TR3.

Note that the substrate SB1 having the metal pattern 126 formed in the above manner may be joined to the substrate SB2. In this case, the metal pattern 126 on the substrate SB1 can be joined to the metal pattern exposed on the surface of the substrate SB2.

The above is an application example of the dual damascene method. However, a conductive plug may be formed instead of the dummy plug 153 and may be used as a via plug without being removed in step S42. Such a method is called a single damascene method.

According to the above method, the formation and processing of the interlayer dielectric films 122a and 122b to which the damascene method is applied are executed without using any vacuum process. In addition, forming the interlayer dielectric films 122a and 122b using a curable composition can contribute to the expansion of the range of choices of materials.

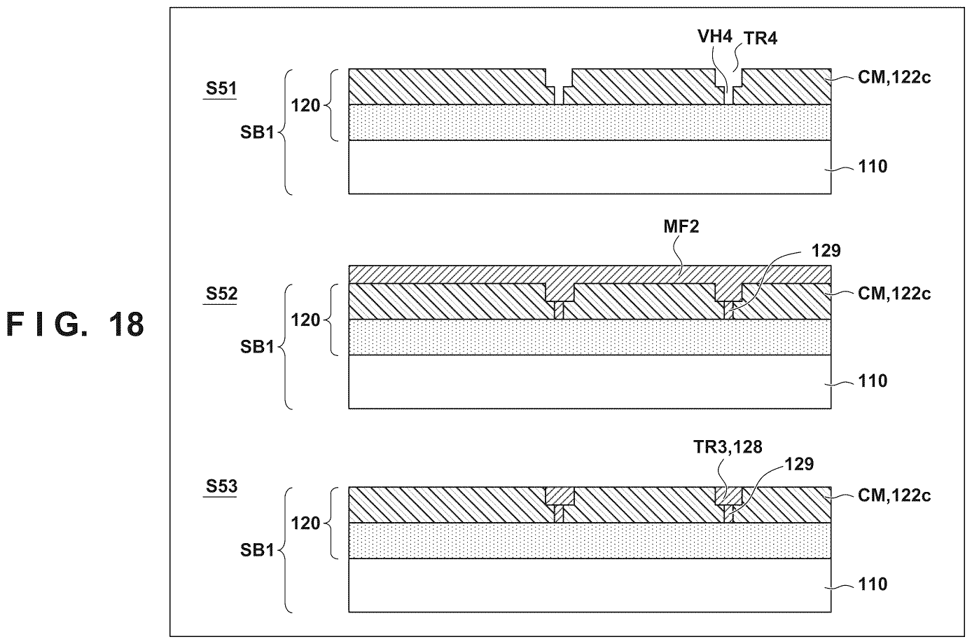

The second example of the manufacturing method for the semiconductor device 100 according to the second embodiment shown in FIG. 15 will be exemplarily described below with reference to FIG. 18. Note that an application example of the dual damascene method will be described below. In step S51, an insulating film forming step can be executed to form, on the semiconductor substrate 110, an insulating film or an interlayer dielectric film 122c made of a cured product of the curable composition CM and having a via hole VH4 and a trench TR4. Note that the interlayer dielectric film 122c corresponds to the multilayer film formed by the interlayer dielectric films 122a and 122b described above. An insulating film forming step can be executed by using the imprint apparatus 2. That is, in the insulating film forming step, the interlayer dielectric film 122c can be formed by placing the curable composition CM on the semiconductor substrate 110, bringing the mold M into contact with the curable composition CM, and curing the curable composition CM.

In step S52, a metal film forming step is executed to form the metal film MF2 on the interlayer dielectric film 122c so as to fill the via hole VH4 and the trench TR4 with a metal. Although not shown, before the metal film forming step, a barrier metal can be formed so as to cover the bottom surface and side surface of the via hole VH4, the bottom surface and side surface of the trench TR4, and the upper surface of the interlayer dielectric film 122c. The barrier metal can be formed from, for example, Ta, TaN, or TiN. The barrier metal can be formed by, for example, a sputter method or CVD method. After the barrier metal is formed, the metal film MF can be formed by a plating method. The metal film MF2 can be formed from, for example, copper or an alloy containing copper as a main component.

In step S53, a polishing step can be executed to polish the metal film MF by a CMP method so as to leave the metal pattern 128 in the via hole VH4 and the trench TR4. In other words, in step S53, a polishing step can be executed to polish the metal film MF2 by the CMP method so as to form the metal pattern 128 in the via hole VH4 and the trench TR4.

Note that the substrate SB1 having the metal pattern 126 formed in the above manner may be joined to the substrate SB2. In this case, the metal pattern 126 on the substrate SB1 can be joined to the metal pattern exposed on the surface of the substrate SB2.

According to the above method, the formation and processing of the interlayer dielectric film 122c to which the damascene method is applied are executed without using any vacuum process. In addition, forming the interlayer dielectric film 122c using a curable composition can contribute to the expansion of the range of choices of materials.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-219008, filed Dec. 13, 2024, which is hereby incorporated by reference herein in its entirety.

What is claimed is:

1. A manufacturing method for a semiconductor device, the method comprising:
forming a depression in an interlayer dielectric film placed on a semiconductor substrate;
forming a planarized film made of a first cured product of a first curable composition on the interlayer dielectric film so as to cover the depression;
forming, on the planarized film, a pattern made of a second cured product of a second curable composition and having an opening on the depression;
etching the planarized film by using the pattern so as to form a trench in the first cured product in the depression;
forming a metal film on the interlayer dielectric film so as to fill the trench with a metal; and
polishing the metal film by a chemical mechanical polishing (CMP) method so as to leave a metal pattern in the trench.

2. The method according to claim 1, wherein in the forming the pattern, the pattern is formed so as to have a first region having a first height and a second region placed between the first region and the opening and having a second height higher than the first height.

3. The method according to claim 1, wherein a polishing rate of the first cured product in the polishing is lower than a polishing rate of the interlayer dielectric film in the polishing.

4. The method according to claim 1, wherein in the forming the planarized film, the planarized film is formed by placing the first cured product on the interlayer dielectric film, bringing a superstrate into contact with the first curable composition, and curing the first curable composition, and
in the forming the pattern, the pattern is formed by placing the second curable composition on the planarized film, bringing a mold into contact with the second cured product, and curing the second curable composition.

5. The method according to claim 1, wherein the interlayer dielectric film includes an inorganic insulating film.

6. The method according to claim 1, wherein the first curable composition and the second curable composition are photo-curable compositions.

7. A manufacturing method for a semiconductor device, the method comprising:
forming a depression in an interlayer dielectric film placed on a semiconductor substrate;
forming, on the interlayer dielectric film, a pattern made of a cured product of a curable composition and having an opening on the depression so as to cover the depression;
etching the overall pattern so as to form a trench in the cured product in the depression;
forming a metal film on the pattern so as to fill the trench with a metal; and
polishing the metal film by a chemical mechanical polishing (CMP) method so as to leave a metal pattern in the trench.

8. The method according to claim 7, wherein in the forming the pattern, the pattern is formed so as to have a first region having a first height and a second region placed between the first region and the depression and having a second height higher than the first height.

9. The method according to claim 7, wherein a polishing rate of the cured product in the polishing is lower than a polishing rate of the interlayer dielectric film in the polishing.

10. The method according to claim 7, wherein in the forming the pattern, the pattern is formed by placing the curable composition on the interlayer dielectric film, bringing a mold into contact with the curable composition, and curing the curable composition.

11. The method according to claim 7, wherein the interlayer dielectric film includes an inorganic insulating film.

12. The method according to claim 7, wherein the curable composition is a photo-curable composition.

13. A manufacturing method for a semiconductor device, the method comprising:
forming a first insulating film made of a first cured product of a first curable composition on a semiconductor substrate;
forming, on the first insulating film, a second insulating film made of a second cured product of a second curable composition and having a trench;
forming a metal film on the second insulating film so as to fill the trench with a metal; and
polishing the metal film by a chemical mechanical polishing (CMP) method so as to leave a metal pattern in the trench.

14. The method according to claim 13, wherein in the forming the first insulating film, the first insulating film is formed by placing the first curable composition on the semiconductor substrate, bringing a superstrate into contact with the first curable composition, and curing the first curable composition, and
in the forming the second insulating film, the second insulating film is formed by placing the second curable composition on the first insulating film, bringing a mold into contact with the second curable composition, and curing the second curable composition.

15. The method according to claim 13, wherein the first curable composition and the second curable composition are photo-curable compositions.

16. A manufacturing method for a semiconductor substrate, the method comprising:
forming, on a semiconductor substrate, an insulating film made of a cured product of a curable composition and having a trench;
forming a metal film on the insulating film so as to fill the trench with a metal; and
polishing the metal film by a chemical mechanical polishing (CMP) method so as to leave a metal pattern in the trench.

17. The method according to claim 16, wherein in the forming the insulating film, the insulating film is formed by placing the curable composition on the semiconductor substrate, bringing a mold into contact with the curable composition, and curing the curable composition.

18. The method according to claim 16, wherein the curable composition is a photo-curable composition.
